(19) United States
(12) Patent Application Publication
(10) Pub. No.: US 2022/0399468 A1
(43) Pub. Date: Dec. 15, 2022

(54) APPARATUS FOR MANUFACTURING A PHOTOVOLTAIC ARRANGEMENT COMPRISING A CONDUCTIVE TAB ELEMENT AND A PLURALITY OF OVERLAPPING SOLAR CELL PIECES, METHOD OF MANUFACTURING SAME

(71) Applicant: APPLIED MATERIALS ITALIA S.R.L., San Biagio di Callalta (IT)

(72) Inventors: Daniele GISLON, Venice (IT); Luigi DE SANTI, Spresiano (tv) (IT); Enrico BOSCOLO MARCHI, Chioggia (IT)

(21) Appl. No.: 17/770,225

(22) PCT Filed: Nov. 7, 2019
(86) PCT No.: PCT/EP2019/080555

§ 371 Date: Apr. 19, 2022

(51) Int. Cl. H01L 31/05; H01L 31/18

(52) U.S. Cl. CPC H01L 31/0504; H01L 31/188

(57) ABSTRACT

An apparatus (100) for manufacturing a photovoltaic arrangement is provided. The photovoltaic arrangement includes a conductive tab element (30) and a plurality of overlapping solar cell pieces. The apparatus includes an assembling module (300). The assembling module is configured for assembling a partial photovoltaic arrangement including a first solar cell piece (10a) and the conductive tab element. The assembling of the partial photovoltaic arrangement includes providing the first solar cell piece and the conductive tab element in an overlapping configuration. The assembling module is configured for providing a second solar cell piece (10b) and a solar cell piece of the partial photovoltaic arrangement in an overlapping configuration. The solar cell piece of the partial photovoltaic arrangement may be the first solar cell piece or a third solar cell piece (10c). Providing the second solar cell piece and the solar cell piece of the partial photovoltaic arrangement in an overlapping configuration is performed after providing the first solar cell piece and the conductive tab element in an overlapping configuration.

### FIELD

Embodiments of the present disclosure relate to photovoltaic arrangements including a plurality of overlapping solar cell pieces, or shingled photovoltaic arrangements. More specifically, embodiments described herein relate to an apparatus and a method for manufacturing a photovoltaic arrangement comprising a conductive tab element and a plurality of overlapping solar cell pieces.

### BACKGROUND

Solar cells are photovoltaic devices that convert sunlight directly into electrical power. The efficiency of the solar cells can be affected by an active area on a front surface of the solar cell which is exposed to light for converting sunlight into electrical power. The active area can be reduced due to the presence of electrical contacts, such as fingers and/or bus bars, on the front surface of the solar cells. The presence of the electrical contacts on the front surface of the solar cells can thus reduce a module power of a solar cell module including the solar cells.

Shingled photovoltaic arrangements can increase an output power of a solar cell module. The increase in the output power can be affected by a quality of a manufacturing process, such as a quality of the elements used to assemble the shingled photovoltaic arrangement. Further, a proper assembling of the shingled photovoltaic arrangement can be cumbersome, and a throughput and/or yield can be low.

In view of the above, new methods and apparatuses for processing solar cells for the manufacture of shingled photovoltaic arrangements that overcome at least some of the problems in the art are beneficial. The present disclosure particularly aims at improving the manufacturing process of photovoltaic arrangements, such as shingled photovoltaic arrangements.

### SUMMARY

According to an embodiment, an apparatus for manufacturing a photovoltaic arrangement is provided. The photovoltaic arrangement includes a conductive tab element and a plurality of overlapping solar cell pieces. The apparatus includes an assembling module. The assembling module is configured for assembling a partial photovoltaic arrangement including a first solar cell piece and the conductive tab element. The assembling of the partial photovoltaic arrangement includes providing the first solar cell piece and the conductive tab element in an overlapping configuration. The assembling module is configured for providing a second solar cell piece and a solar cell piece of the partial photovoltaic arrangement in an overlapping configuration. The solar cell piece of the partial photovoltaic arrangement may be the first solar cell piece or a third solar cell piece. Providing the second solar cell piece and the solar cell piece of the partial photovoltaic arrangement in an overlapping configuration is performed after providing the first solar cell piece and the conductive tab element in an overlapping configuration.

According to a further embodiment, an apparatus for manufacturing a photovoltaic arrangement is provided. The apparatus includes an assembling module for assembling a photovoltaic arrangement comprising a conductive tab element and a plurality of overlapping solar cell pieces. The apparatus includes a heating module downstream of the assembling module to cure the photovoltaic arrangement including the conductive tab element and the plurality of overlapping solar cell pieces.

According to a further embodiment, a method of manufacturing a photovoltaic arrangement comprising a conductive tab element and a plurality of overlapping solar cell pieces is provided. The method includes assembling a partial photovoltaic arrangement comprising a first solar cell piece and the conductive tab element, the assembling comprising providing the first solar cell piece and the conductive tab element in an overlapping configuration. The method includes providing a second solar cell piece and a solar cell piece of the partial photovoltaic arrangement in an overlapping configuration. The solar cell piece of the partial photovoltaic arrangement is the first solar cell piece or a third solar cell piece. The second solar cell piece and the solar cell piece of the partial photovoltaic arrangement are provided in an overlapping configuration after the first solar cell piece and the conductive tab element are provided in an overlapping configuration.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows an example of a solar cell piece as described herein;

FIG. 2 shows an example of a photovoltaic arrangement including a plurality of overlapping solar cell pieces and a conductive tab element as described herein;

FIGS. 3a-c and 4a-c illustrate an exemplary mode of operation of an assembling module of an apparatus according to embodiments described herein;

FIGS. 5a-c show examples of a positioning device of an assembling module as described herein;

FIG. 6 shows an example of solar cell pieces and a conductive tab element being transported in a transport direction;

FIG. 7 shows an apparatus according to embodiments described herein including a storing unit for storing a conductive tab element;

FIG. 8 shows an apparatus according to embodiments described herein including a solar cell cleaving device, an adhesive application device and a heating module;

FIGS. 9a-c illustrate an exemplary mode of operation of an assembling module of an apparatus according to embodiments described herein;

FIG. 10 shows an example of overlapping configuration including a conductive tab element and a first and second solar cell piece;

FIGS. 11a-b illustrate an exemplary mode of operation of an assembling module of an apparatus according to embodiments described herein; and

FIGS. 12a-b illustrate an apparatus according to embodiments described herein.

### DETAILED DESCRIPTION

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Embodiments described herein relate to shingled photovoltaic arrangements, or shingled solar cell arrangements. A shingled photovoltaic arrangement can include a plurality of overlapping solar cell pieces. Adjacent solar cell pieces in the shingled photovoltaic arrangement overlap with each other and are electrically connected to each other in the overlapping region, e.g. via adhesives as described herein. The solar cell pieces are connected in series such that current generated by the individual solar cell pieces flows along the series of solar cell pieces to be collected, for example, at an end portion of the shingled photovoltaic arrangement. The overlapping configuration can provide high-efficiency photovoltaic arrangements. In particular, shingled photovoltaic arrangements allow for increasing a solar cell module power by increasing a used or active area. Typically, the overlapping configuration can increase the module power by, for example, 20 to 40 Watts. The used or active area can correspond to an area that is irradiated by solar light and that participates in the generation of power. For example, the used or active area can correspond to an area of the solar cells that is not covered by, for example, conductive line patterns, such as fingers and/or bus bars.

A photovoltaic arrangement, as described herein, can be understood as a shingled photovoltaic arrangement.

The term “solar cell piece”, as used herein, refers to a piece, portion or segment of a solar cell. A solar cell piece may be understood as a solar cell segment, or solar cell shingle. A solar cell piece may be a portion of a solar cell resulting from cleaving the solar cell, i.e. separating the solar cell into solar cell pieces. The area of a solar cell piece is smaller than the area of a solar cell. In some cases, a solar cell piece may have an area of 50% or less of the area of a solar cell.

A solar cell piece, as described herein, may include a conductive pattern, particularly a conductive line pattern. A conductive pattern can include one or more bus bars and/or a plurality of fingers. A solar cell piece can include a conductive pattern on a front side of the solar cell piece. Additionally or alternatively, a solar cell piece can include a conductive pattern on a back side of the solar cell piece. For example, a solar cell piece can include a first conductive pattern including a first bus bar and a plurality of fingers on the front side of the solar cell or solar cell piece. The solar cell piece can include a second conductive pattern including a second bus bar on the back side of the solar cell piece. A solar cell piece can include a single bus bar on a first side of the solar cell piece. A solar cell piece can include a single bus bar on a second side of the solar cell piece opposite the first side.

A solar cell or solar cell piece, as described herein, can be a silicon solar cell or silicon solar cell piece, respectively.

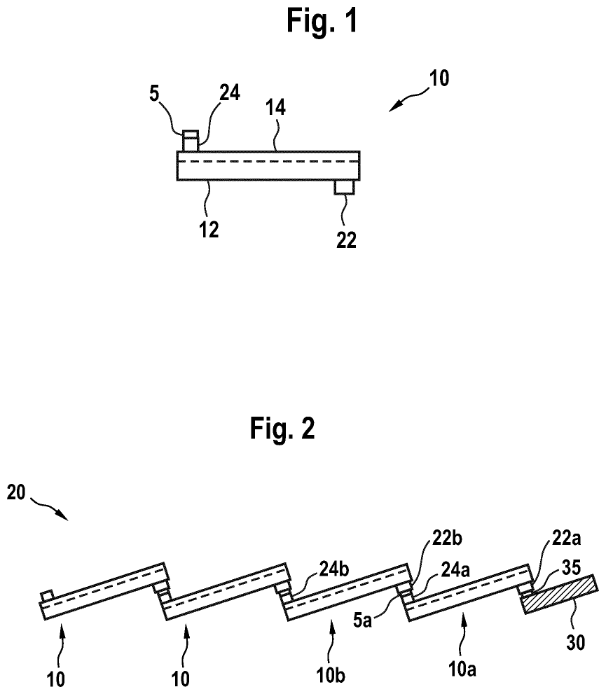

FIG. 1 shows an example of a solar cell piece 10 as described herein.

A solar cell piece 10 may have a back side 12 and a front side 14 opposite the back side 12. The front side 14 may be configured for receiving light, e.g. sunlight, which may be converted into electrical power by the solar cell piece 10. A solar cell piece 10 may include a bus bar 24. The bus bar 24 may be provided on the front side of the solar cell piece 10. The solar cell piece 10 may include a bus bar 22. The bus bar 22 may be provided on the back side 12 of the solar cell piece 10. A solar cell piece 10 may include an adhesive 5. The adhesive 5 may be provided on the front side 14 of the solar cell piece 10. In some implementations, the adhesive 5 may be provided on the bus bar 24. Alternatively, the adhesive 5 may be provided on the back side 12 of the solar cell piece 10, such as e.g. on the bus bar 22.

An adhesive as described herein may be configured for connecting, bonding or attaching solar cell pieces to each other. An adhesive can be configured for connecting a solar cell piece of a photovoltaic arrangement to a further solar cell piece of the photovoltaic arrangement. The adhesive can provide for an electrical and mechanical connection between two solar cell pieces of a photovoltaic arrangement.

Additionally or alternatively, an adhesive as described herein may be configured for connecting, bonding or attaching a solar cell piece to a conductive tab element. The adhesive can provide for an electrical and mechanical connection between the solar cell piece and the conductive tab element.

An adhesive as described herein can be an electrically conductive adhesive (ECA). An adhesive can be selected from the group consisting of solder, silver paste, silicone-based electrically conductive adhesive, and epoxy-based electrically conductive adhesive.

FIG. 2 shows an example of a photovoltaic arrangement 20 as described herein.

A photovoltaic arrangement 20 may include a first solar cell piece, e.g. solar cell piece 10a. The photovoltaic arrangement 20 may include a second solar cell piece, e.g. solar cell piece 10b. The second solar cell piece may overlap with the first solar cell piece. The first solar cell piece and the second solar cell piece may be adjacent solar cell pieces of the photovoltaic arrangement 20. The first solar cell piece 1 may be connected, bonded or attached to the second solar cell piece by an adhesive 5a. In some implementations, the adhesive 5a may bond a bus bar 24a of the first solar cell piece to a bus bar 22b of the second solar cell piece.

A photovoltaic arrangement 20 may include a plurality of further solar cell pieces 10. A photovoltaic arrangement 20 may include a plurality of adhesives connecting adjacent solar cell pieces 10 of the photovoltaic arrangement 20.

A photovoltaic arrangement 20 may include a conductive tab element 30. A conductive tab element 30 can be referred to as a ribbon or ribbon element. A conductive tab element 30 may be configured for electrically connecting the photovoltaic arrangement 20 to an external entity. For example, by way of the conductive tab element 30, the photovoltaic arrangement 20 can be electrically connected to a further photovoltaic arrangement, e.g. by connecting the conductive tab element 30 to a further conductive tab element of the further photovoltaic arrangement. In another implementation, a plurality of photovoltaic arrangements similar to photovoltaic arrangement 20 can be mounted together in a module, wherein each photovoltaic arrangement of the module is electrically coupled to the module by the conductive tab element of the respective photovoltaic arrangement.

In a photovoltaic arrangement 20 as described herein, a conductive tab element 30 can be attached to a last solar cell piece of the photovoltaic arrangement 20. A last solar cell piece of a photovoltaic arrangement 20 can be understood as a solar cell piece having only one adjacent solar cell piece in the photovoltaic arrangement 20. For example, in FIG. 2, the solar cell piece 10a has only one adjacent solar cell piece in the photovoltaic arrangement 20, namely the solar cell piece 10b. In FIG. 2, the solar cell piece 10a is a last solar cell piece of the photovoltaic arrangement 20.

A conductive tab element 30 may be a flat piece of conductive material, e.g. a plate-like element. A conductive tab element may be a metal element, e.g. a copper element. A conductive tab element may include or be made of copper. A conductive tab element may be a copper element coated with a material, such as solder. A conductive tab element may have a length which is comparable to a length of the solar cell piece to which the conductive tab element is attached. A conductive tab element as described herein is not a solar cell piece or solar cell.

The conductive tab element 30 may be connected, bonded or attached to the first solar cell piece by a first adhesive, e.g. adhesive 35 shown in FIG. 2. In some implementations, the first adhesive may bond the conductive tab element 30 to a bus bar 22a of the first solar cell piece.

In some approaches, a photovoltaic arrangement 20 can be manufactured by first assembling all the solar cell pieces of the photovoltaic arrangement 20 in an overlapping configuration, followed by attaching a conductive tab element 30 at an end of the photovoltaic arrangement 20. According to embodiments described herein, the inclusion of the conductive tab element 30 in the photovoltaic arrangement 20 is not a separate operation performed after the solar cell pieces of the photovoltaic arrangement 20 have been overlapped with each other. According to embodiments described herein, said inclusion of the conductive tab element 30 is incorporated as an integral part of the assembling process of the photovoltaic arrangement 20. In particular, the photovoltaic arrangement 20 is assembled by starting out from the conductive tab element 30 and thereafter gradually building up the rest of the photovoltaic arrangement 20 by consecutively adding solar cell pieces to the arrangement.

Embodiments described herein provide the advantage that there is no need to handle a lengthy arrangement of overlapping solar cell pieces when attaching the conductive tab element of the photovoltaic arrangement. Particularly, a photovoltaic arrangement can typically include several dozens of solar cell pieces and can in some cases be several meters in length. Embodiments described herein avoid handling such lengthy arrangements for the attachment of the conductive tab element 30. In light thereof, the footprint of the apparatus can be considerably reduced. For example, an approach in which the attachment of conductive tab element 30 is performed as a separate operation, i.e. after the solar cell pieces have been assembled, can involve the provision of a tabbing module located downstream of the assembling module having several meters in length for attaching the conductive tab element. In comparison, in an apparatus according to embodiments described herein, such an additional tabbing module can be avoided. The additional space that would be taken up by the tabbing module can be saved, so that the apparatus can be made several meters shorter. The footprint of the apparatus can be reduced.

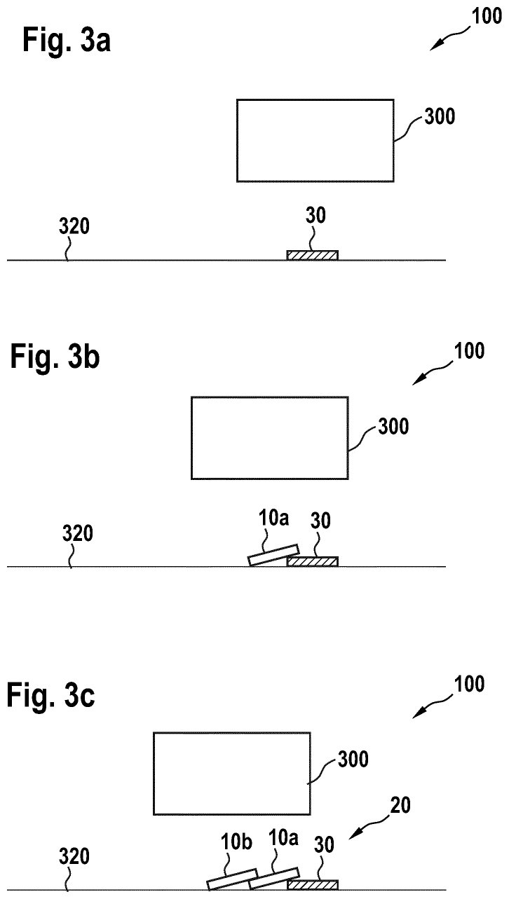

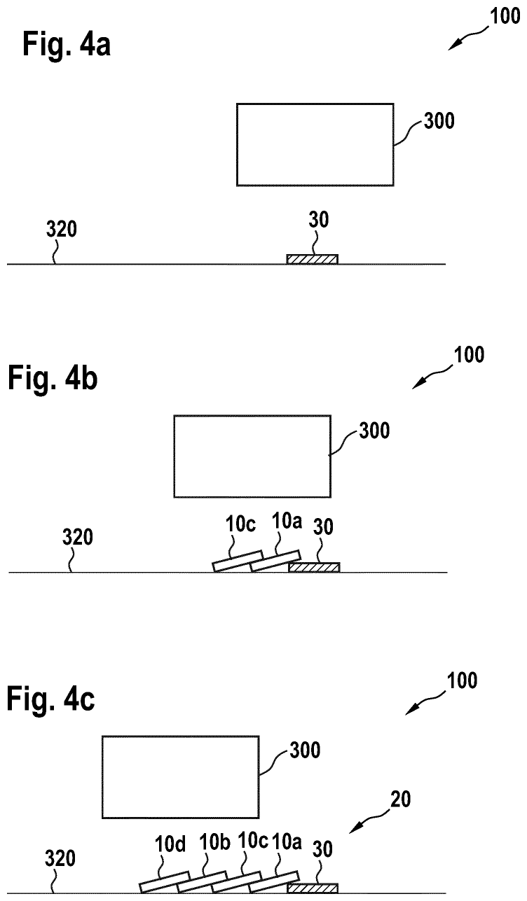

FIGS. 3a-c show an apparatus 100 for manufacturing a photovoltaic arrangement 20 including a conductive tab element 30 and a plurality of overlapping solar cell pieces according to embodiments described herein. The apparatus 100 includes an assembling module 300. For example, the assembling module 300 may include one or more positioning devices, such as a first pick-and-place device for gripping and moving solar cell pieces and a second pick-and-place device for gripping and moving conductive tab element 30.

FIGS. 3a, 3b and 3c illustrate three operations which can be carried out by the assembling module 300 in the order indicated. The operation illustrated in FIG. 3a can be performed before the operation illustrated in FIG. 3b. The operation illustrated in FIG. 3b can be performed before the operation illustrated in FIG. 3c.

As shown for example in FIG. 3a, an assembling module 300 as described herein may be configured for placing a conductive tab element 30 on a first support surface 320.

As shown for example in FIG. 3b, an assembling module 300 as described herein may be configured for providing a solar cell piece 10a and the conductive tab element 30 in an overlapping configuration. For example, the assembling module 300 may be configured to place the solar cell piece 10a on the first support surface 320 in a manner such that a portion of the solar cell piece 10a rests upon and overlaps with a portion of the conductive tab element 30.

As shown for example in FIG. 3c, an assembling module 300 as described herein may be configured for providing a solar cell piece 10b and the solar cell piece 10a in an overlapping configuration. For example, the assembling module 300 may be configured to place the solar cell piece 10b on the first support surface 320 in a manner such that a portion of the solar cell piece 10b rests upon and overlaps with a portion of the solar cell piece 10a.

The assembling module 300 may place a further solar cell piece on the first support surface 320 to overlap with the solar cell piece 10b, and continue in this manner by adding further solar cell pieces in an overlapping configuration with respect to the solar cell piece positioned previously on the first support surface, until the photovoltaic arrangement 20 is fully assembled.

The exemplary assembling module 300 shown in FIGS. 3a-c may be configured for gripping and moving individual solar cell pieces. Alternatively, an assembling module 300 may be configured for gripping and moving multiple solar cell pieces jointly, as illustrated in FIGS. 4a-c. Similar to FIGS. 3a-c, FIGS. 4a, 4b and 4c illustrate three operations which can be carried out by the assembling module 300 in the order indicated.

Similar to FIG. 3a, FIG. 4a illustrates that the assembling module 300 may be configured for placing the conductive tab element 30 on the first support surface 320.

The assembling module 300 may be configured for gripping and moving at least two solar cell pieces jointly, such as solar cell piece 10a and solar cell piece 10c shown in FIG. 4b. The assembling module 300 may be configured for providing the solar cell piece 10a and the conductive tab element 30 in an overlapping configuration. The assembling module 300 may be configured for providing the solar cell piece 10c and the solar cell piece 10a in an overlapping configuration. For example, the assembling module 300 may be configured to place the solar cell piece 10a and the solar cell piece 10c on the first support surface 320 in a manner such that a portion of the solar cell piece 10a rests upon and overlaps with a portion of the conductive tab element 30 and such that a portion of the solar cell piece 10c rests upon and overlaps with a portion of the solar cell piece 10a.

The assembling module 300 may be configured for gripping and moving two further solar cell pieces jointly, such as solar cell piece 10b and solar cell piece 10d shown in FIG. 4c. The assembling module 300 may be configured for providing the solar cell piece 10b and the solar cell piece 10c in an overlapping configuration. The assembling module 300 may be configured for providing the solar cell piece 10d and the solar cell piece 10b in an overlapping configuration. For example, the assembling module 300 may be configured to place the solar cell piece 10b and the solar cell piece 10d on the first support surface 320 in a manner such that a portion of the solar cell piece 10b rests upon and overlaps with a portion of the solar cell piece 10c and such that a portion of the solar cell piece 10d rests upon and overlaps with a portion of the solar cell piece 10b.

In light of the above, according to an embodiment, an apparatus 100 for manufacturing a photovoltaic arrangement is provided. The photovoltaic arrangement includes a conductive tab element 30 and a plurality of overlapping solar cell pieces. The apparatus 100 includes an assembling module 300. The assembling module 300 is configured for assembling a partial photovoltaic arrangement including a first solar cell piece and the conductive tab element 30. The assembling of the partial photovoltaic arrangement includes providing the first solar cell piece and the conductive tab element 30 in an overlapping configuration. The assembling module 300 is configured for providing a second solar cell piece and a solar cell piece of the partial photovoltaic arrangement in an overlapping configuration. The solar cell piece of the partial photovoltaic arrangement may be the first solar cell piece or a third solar cell piece. Providing the second solar cell piece and the solar cell piece of the partial photovoltaic arrangement in an overlapping configuration is performed after providing the first solar cell piece and the conductive tab element in an overlapping configuration.

For example, with respect to the figures, the first solar cell piece as described herein can be understood as the solar cell piece 10a. The partial photovoltaic arrangement can be understood as the arrangement shown in FIG. 3b including the conductive tab element 30 and the solar cell piece 10a, or as the arrangement shown in FIG. 4b including the conductive tab element 30, the solar cell piece 10a and the solar cell piece 10c. The second solar cell piece can be understood as the solar cell piece 10b. The third solar cell piece may be understood as the solar cell piece 10c.

It shall be understood that the sequences of operations illustrated in FIGS. 3a-c and 4a-c are exemplary and for the purpose of illustration, and that other ways can be considered for placing the conductive tab element 30 and the solar cell pieces on the first support surface 320 in accordance with embodiments described herein. For example, the assembling module 300 can be configured for positioning three or more solar cell pieces simultaneously on the first support surface 320, for gripping and moving the conductive tab element 30 and one or more solar cell pieces jointly, and so on.

An apparatus 100 according to embodiments described herein may include a first support surface 320. The first support surface 320 may be a surface of a transportation unit, e.g. a conveyor, of the apparatus 100. The first support surface 320 may be for receiving the first solar cell piece, the second solar cell piece, the third solar cell pieces and/or the conductive tab element 30.

An assembling module 300 as described herein may include one or more positioning devices. The one or more positioning devices may be for placing the conductive tab element 30, the first solar cell piece, the second solar cell piece and/or the third solar cell piece on the first support surface 320.

An assembling module 300 as described herein may include a controller connected to the one or more positioning devices. The controller may be configured to control a movement of the one or more positioning devices in a manner such that the first solar cell piece and the conductive tab element 30 are provided in an overlapping configuration by the one or more positioning devices and/or the second solar cell piece and a solar cell piece of the partial photovoltaic arrangement are provided in an overlapping configuration by the one or more positioning devices.

The assembling module 300 may include a first positioning device, e.g. a first pick-and-place device, for positioning the first solar cell piece on the first support surface 320, e.g. under the control of the controller. The first positioning device may be configured for positioning the second solar cell piece on the first support surface 320, e.g. under the control of the controller. The first positioning device may be configured for positioning the third solar cell piece on the first support surface 320 e.g. under the control of the controller. An example of a first positioning device may be the positioning device 715 discussed below with respect to FIG. 7.

The assembling module 300 may include a second positioning device, e.g. a second pick-and-place apparatus, for positioning the conductive tab element 30 on the first support surface 320 e.g. under the control of the controller. An example of a second positioning device may be the positioning device 725 discussed below with respect to FIG. 7. The conductive tab element 30 and the first solar cell piece may be positioned on the first support surface 320 by different positioning devices of the assembling module 300, such as the first positioning device and the second positioning device.

Alternatively, the first positioning device as described herein may be configured for positioning the conductive tab element 30 on the first support surface 320. One positioning device, such as the first positioning device, may be configured for positioning the first solar cell piece on the first support surface 320 and for positioning the conductive tab element 30 on the first support surface 320, e.g. under the control of the controller. For example, the first positioning device may be configured to position the conductive tab element 30 on the first support surface 320 and thereafter position the first solar cell piece on the first support surface 320.

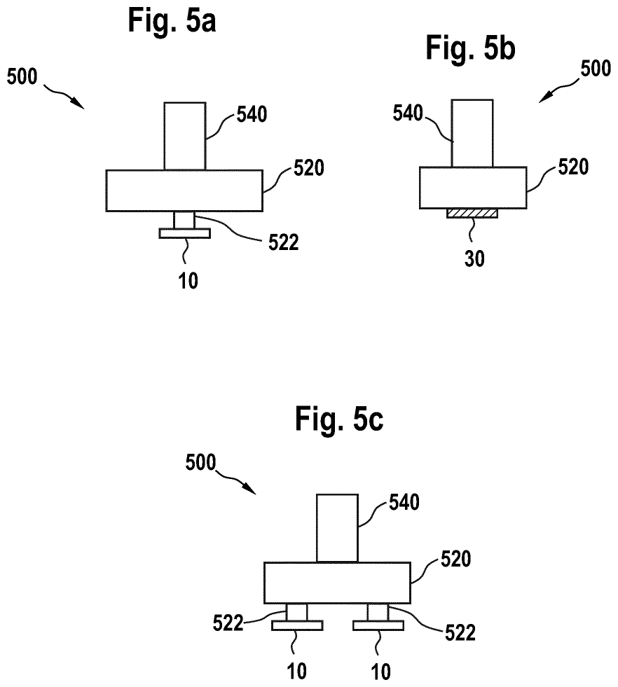

FIGS. 5a-c show different examples of a positioning device 500, e.g. the first positioning device and/or the second positioning device as described herein.

A positioning device 500 as described herein may include a gripper 520. The gripper 520 may be for holding one or more solar cell pieces and/or for holding the conductive tab element 30. A gripper 520 may include one or more suction cups 522. Other devices for holding the solar cell piece(s) and/or the conductive tab element may be used. A gripper 520 may be configured to hold and/or move a plurality of solar cell pieces jointly, e.g. two, three, four, five, six or even more solar cell pieces. A positioning device 500 may include a mechanical arm 540. The gripper 520 may be coupled to the mechanical arm 540. A positioning device 500 may include an actuator to move, particularly lift, the gripper 520.

For example, FIG. 5a shows a positioning device 500 including a gripper 520 for holding a solar cell piece 10 as a single solar cell piece held by the gripper 520. FIG. 5b shows a positioning device 500 including a gripper 520 for holding a conductive tab element 30. FIG. 5c shows a positioning device 500 including a gripper 520 for holding two solar cell pieces 10 jointly.

For example, the positioning device 500 shown in FIG. 5b may be used for placing the conductive tab element 30 on the first support surface 320 in the manner illustrated in FIG. 3a. The positioning device 500 shown in FIG. 5a may be used for placing the solar cell piece 10a on the first support surface 320 in the manner illustrated in FIG. 3b and, thereafter, for placing the solar cell piece 10b on the first support surface 320 in the manner illustrated in FIG. 3c.

For example, the positioning device 500 shown in FIG. 5b may be used for placing the conductive tab element 30 on the first support surface 320 in the manner illustrated in FIG. 4a. The positioning device 500 shown in FIG. 5c may be used for placing the solar cell piece 10a and the solar cell piece 10c on the first support surface 320 in the manner illustrated in FIG. 4b and, thereafter, for placing the solar cell piece 10b and the solar cell piece 10d on the first support surface 320 in the manner illustrated in FIG. 4c.

It shall be understood that the positioning devices shown in FIGS. 5a-c are merely exemplary, and that other positioning devices can be considered for assembling the photovoltaic arrangement 20 in accordance with embodiments described herein.

An assembling module 300 as described herein may include one or more positioning devices configured to place the conductive tab element 30 on the first support surface 320 and, thereafter, place the first solar cell piece on the first support surface 320. The one or more positioning devices may be configured to place the first solar cell piece on the first support surface 320 in a manner such that an end portion of the first solar cell piece is placed on, or supported by, an end portion of the conductive tab element 30.

A controller as described herein may be configured to control a movement of the one or more positioning devices in a manner such that the conductive tab element 30 is placed on the first support surface 320 by the one or more positioning devices and, thereafter, the first solar cell piece is placed on the first support surface 320 by the one or more positioning devices.

The one or more positioning devices may be configured to place the second solar cell piece on the first support surface 320 in a manner such that an end portion of the second solar cell piece is placed on, or supported by, an end portion of a solar cell piece of the partial photovoltaic arrangement as described herein. The solar cell piece of the partial photovoltaic arrangement may be the first solar cell piece or the third solar cell piece as described herein.

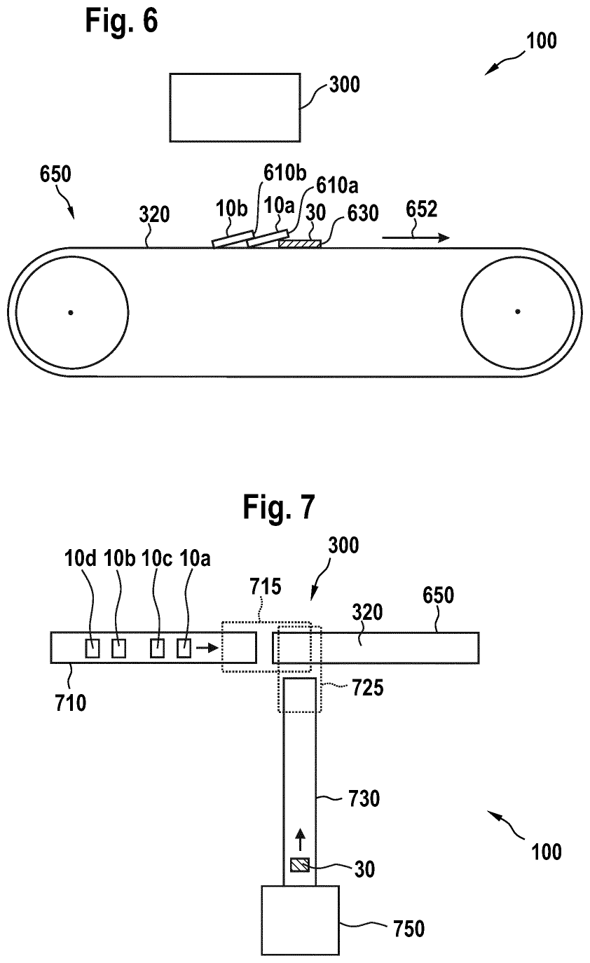

An apparatus 100 according to embodiments described herein may include a transportation unit 650, as shown for example in FIG. 6. The transportation unit 650 may include one or more conveyors, e.g. belt conveyors. The transportation unit 650 may define a transport direction 652. The transportation unit 650 may be configured for transporting solar cell pieces, e.g. the first solar cell piece, the second solar cell piece and/or the third solar cell piece, in the transport direction 652. The transportation unit 650 may be configured for transporting the conductive tab element 30 in the transport direction 652. The first support surface 320 may be a surface of the transportation unit 650.

The one or more positioning devices of the assembling module 300 may be configured to place the conductive tab element 30 and the first solar cell piece on the first support surface 320 in a manner such that a leading edge of the first solar cell piece follows a leading edge of the conductive tab element 30. For example, in FIG. 6, the solar cell piece 10a (“first solar cell piece”) has a leading edge 610a and the conductive tab element 30 has a leading edge 630. The leading edge of the conductive tab element 30 can be understood as the first edge, or front edge, of the conductive tab element 30 relative to the movement of the conductive tab element 30 in the transport direction 652. The leading edge of the first solar cell piece can be understood as the first edge, or front edge, of the first solar cell piece relative to the movement of the first solar cell piece in the transport direction 652. That the leading edge of the first solar cell piece follows the leading edge of the conductive tab element 30 can be understood relative to the movement of the first solar cell piece and the conductive tab element 30 in the transport direction 652. The leading edge of the first solar cell piece is behind the leading edge of the conductive tab element 30 relative to said movement in the transport direction 652.

A controller as described herein may be configured to control a movement of the one or more positioning devices in a manner such that the conductive tab element 30 and the first solar cell piece are placed on the first support surface 320 by the one or more positioning devices, wherein a leading edge of the first solar cell piece follows a leading edge of the conductive tab element 30.

The one or more positioning devices of the assembling module 300 may be configured to place the conductive tab element 30, the first solar cell piece and the second solar cell piece on the first support surface 320 in a manner such that a leading edge of the first solar cell piece follows a leading edge of the conductive tab element 30 and such that a leading edge of the second solar cell piece follows the leading edge of the first solar cell piece. For example, in FIG. 6, the solar cell piece 10b (“second solar cell piece”) has a leading edge 610b which follows the leading edge 610a of the solar cell piece 10a (“first solar cell piece”). The leading edge 610a of the solar cell piece 10a follows the leading edge 630 of the conductive tab element 30.

FIG. 7 shows an apparatus 100 according to embodiments described herein.

An apparatus 100 according to embodiments described herein may include a storing unit 750 for storing the conductive tab element 30. The storing unit 750 may be configured for storing a plurality of conductive tab elements. The storing unit 750 may be a stationary storing unit. The conductive tab element 30 may be stationary while the conductive tab element 30 is stored in the storing unit 750. The storing unit 750 may be a cassette.

An apparatus 100 according to embodiments described herein may include a transfer system. The transfer system may be for transferring the conductive tab element 30 from the storing unit 750 to the first support surface 320. The transfer system may include a transportation unit 730, e.g. one or more conveyors, for transporting the conductive tab element 30 from the storing unit 750 to the first support surface 320. The assembling module 300 may include a positioning device 725 for picking up the conductive tab element 30 from the transportation unit 730 and/or for placing the conductive tab element 30 on the first support surface 320. The first support surface 320 may be a surface of the transportation unit 650. The positioning device 725 may be configured for transferring the conductive tab element 30 from the transportation unit 730 to the transportation unit 650.

An apparatus 100 according to embodiments described herein may include a feeding system for feeding the conductive tab element 30 to the first support surface 320. The feeding system may include a storing unit 750 and a transfer system, as described herein. Alternatively, the feeding system may include a feeding roller, e.g. a reel. The feeding roller may be configured for having a length of conductive tab element material rolled onto the feeding roller. The conductive tab element material may be a conductive material from which a conductive tab element 30 is made. The feeding system may be configured to manufacture a conductive tab element 30 from the conductive tab element material supplied by the feeding roller. For example, the feeding system may include a punching and/or cutting device for manufacturing a conductive tab element 30 from the conductive tab element material. The feeding system may include a transfer system for transferring the manufactured conductive tab element 30 to the first support surface 320.

An apparatus 100 according to embodiments described herein may include a transportation unit 710. The transportation unit 710 may include one or more conveyors, e.g. belt conveyors. The transportation unit 710 may be for transporting solar cell pieces, such as the first solar cell piece, the second solar cell piece and/or the third solar cell piece. The assembling module 300 may include a positioning device 715. The positioning device 715 may be configured for transferring the first solar cell piece, the second solar cell piece and/or the third solar cell piece from the transportation unit 710 to the first support surface 320. The first support surface 320 may be a surface of the transportation unit 650. The positioning device 715 may be configured for transferring the first solar cell piece, the second solar cell piece and/or the third solar cell piece from the transportation unit 710 to the transportation unit 650.

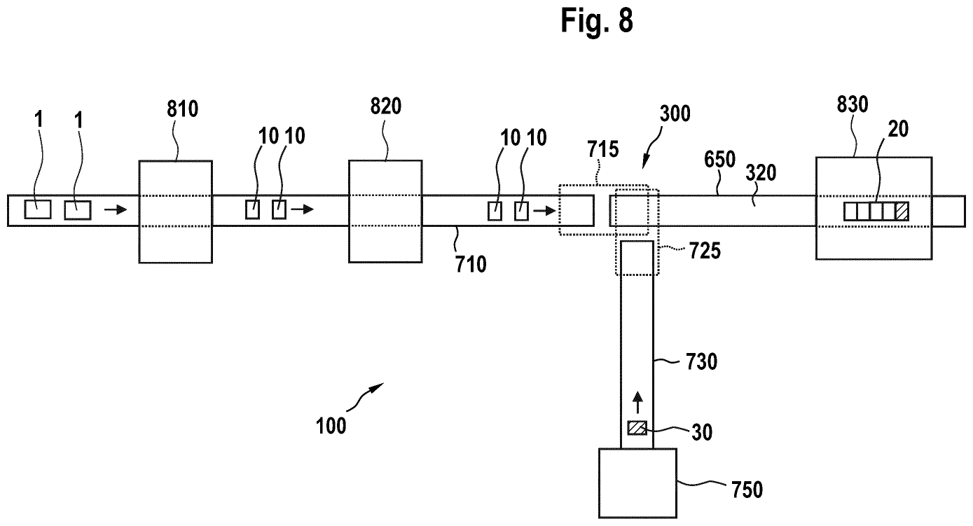

FIG. 8 shows an apparatus 100 according to embodiments described herein. The conductive tab element 30 is transferred from the storing unit 750 to the first support surface 320. In particular, the conductive tab element 30 is placed on the first support surface 320 by the positioning device 725. Solar cells 1 are inputted to a solar cell separation device 810. The solar cells 1 are separated into solar cell pieces 10 by the solar cell separation device 810. The solar cell pieces 10 are transported to a first adhesive application device 820 for applying an adhesive to each solar cell piece 10. The solar cell pieces 10 including the respective adhesives are placed on the first support surface 320 by the positioning device 715. A photovoltaic arrangement including a plurality of overlapping solar cell pieces and a conductive tab element 30 is assembled on the first support surface 320. The photovoltaic arrangement is transported to a heating module 830. The photovoltaic arrangement is heated by the heating module 830 for curing the adhesive connecting the conductive tab element 30 with the first solar cell piece and for curing the adhesives connecting the adjacent solar cell pieces of the photovoltaic arrangement.

The layout of the apparatus 100 shown in FIG. 8 is merely exemplary and for the purpose of illustration, and other layouts of the apparatus 100 can be considered in accordance with embodiments described herein. For example, an apparatus 100 according to embodiments described herein may not include a solar cell separation device 810. In some implementations, pre-formed solar cell pieces provided by a cleaving device external to the apparatus 100 may be supplied, so that a solar cell separation device 810 need not be part of the apparatus 100. Also, the first adhesive application device 820 may be arranged upstream of the solar cell separation device 810 for applying adhesives to full solar cells, i.e. before cleaving the solar cells into solar cell pieces. Further modifications of the apparatus 100 shown in FIG. 8 are possible in accordance with embodiments described herein.

An apparatus 100 according to embodiments described herein may include a solar cell separation device 810. The solar cell separation device 810 may be upstream of the assembling module 300.

A solar cell separation device 810 may be configured for separating a solar cell 1 into two or more solar cell pieces 10. A solar cell separation device 810 may include a cutting device, e.g. a mechanical cutting device or a laser, for cutting a solar cell 1 into two or more solar cell pieces 10. A solar cell separation device 810 may be understood as a solar cell cleaving device.

An apparatus 100 according to embodiments described herein may include a first adhesive application device 820. The first adhesive application device 820 may be upstream of the assembling module 300.

The first adhesive application device 820 may be a printing device, e.g. a screen printing device. The first adhesive application device 820 and the solar cell separation device 810 may be arranged on a same processing line of the apparatus 100. The first adhesive application device 820 may be downstream or upstream of the solar cell separation device 810. The first adhesive application device 820 may be arranged downstream of the solar cell separation device 810 (as e.g. shown in FIG. 8) for applying an adhesive to a solar cell piece 10, such as the first solar cell piece, the second solar cell piece and/or the third solar cell piece as described herein. The solar cell piece 10 may result from separating a solar cell 1 into solar cell pieces by the solar cell separation device 810. Alternatively, the first adhesive application device 820 may be arranged upstream of the solar cell separation device 810 for applying an adhesive to a solar cell 1, before the solar cell 1 is separated into solar cell pieces 10 by the solar cell separation device 810.

An apparatus 100 according to embodiments described herein may include a second adhesive application device. The second adhesive application device may be for applying an adhesive to the conductive tab element 30. The second adhesive application device may be upstream of the assembling module 300. The second adhesive application device may be downstream of the storing unit 750. The second adhesive application device may be configured for dispensing an adhesive through a syringe by a controlled air-pressure.

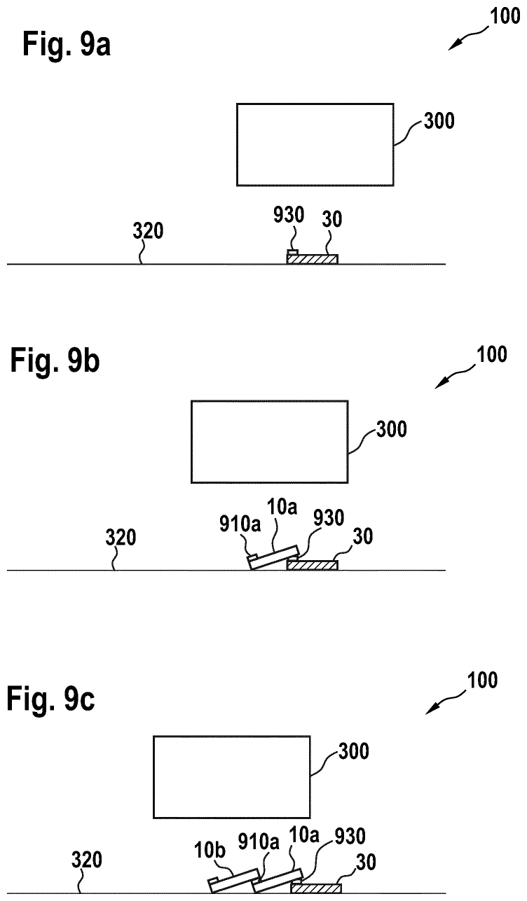

FIGS. 9a-c show an apparatus 100 according to embodiments described herein.

As described herein, the first solar cell piece and the conductive tab element 30 can be provided in an overlapping configuration by the assembling module 300. For example, FIG. 9b shows the solar cell piece 10a and the conductive tab element 30 in an overlapping configuration. In the overlapping configuration, the first solar cell piece may be connected with, or bonded to, the conductive tab element 30 by a first adhesive, e.g. adhesive 930 shown in FIG. 9b or adhesive 35 shown in FIG. 2. In the overlapping configuration, the first adhesive may be arranged in a region where the first solar cell piece overlaps with the conductive tab element 30. When the first solar cell piece and the conductive tab element 30 are provided in the overlapping configuration by the assembling module 300, the first adhesive may be in a substantially liquid or uncured state. An adhesive in a substantially liquid or uncured state may be an adhesive which is a paste.

As described herein, the second solar cell piece and a solar cell piece of the partial photovoltaic arrangement (the latter solar cell piece being the first solar cell piece or the third solar cell piece as described herein) can be provided in an overlapping configuration by the assembling module 300. For example, FIG. 9c shows the solar cell piece 10b and the solar cell piece 10a in an overlapping configuration. In the overlapping configuration, the second solar cell piece may be connected with, or bonded to, the solar cell piece of the partial photovoltaic arrangement by a second adhesive, e.g. second adhesive 910a shown in FIG. 9c. In the overlapping configuration, the second adhesive may be arranged in a region where the second solar cell piece overlaps with the solar cell piece of the partial photovoltaic arrangement. When the second solar cell piece and the solar cell piece of the partial photovoltaic arrangement are provided in the overlapping configuration by the assembling module 300, the second adhesive may be in a substantially liquid state. When the second solar cell piece and the solar cell piece of the partial photovoltaic arrangement are provided in the overlapping configuration by the assembling module 300, the first adhesive (e.g. adhesive 930) may be in a substantially liquid state.

An apparatus 100 according to embodiments described herein may include a heating module 830 downstream of the assembling module 300, as shown for example in FIG. 8. The heating module 830 may be configured to cure the photovoltaic arrangement 20 including the conductive tab element 30 and the plurality of overlapping solar cell pieces. The heating module 830 may be configured to cure a first adhesive (e.g. adhesive 930 shown in FIGS. 9a-c) connecting the first solar cell piece with the conductive tab element 30. The heating module 830 may be configured to cure a second adhesive (e.g. second adhesive 910a shown in FIG. 9b-c) connecting the second solar cell piece with a solar cell piece of the partial photovoltaic arrangement, the latter solar cell piece being the first solar cell piece or the third solar cell piece as described herein. The heating module 830 may be arranged downstream of the assembling module 300 to jointly cure the first adhesive connecting the first solar cell piece with the conductive tab element 30 and the second adhesive connecting the second solar cell piece with the solar cell piece of the partial photovoltaic arrangement (the latter solar cell piece being the first solar cell piece or the third solar cell piece as described herein). The heating module 830 may be arranged downstream of the assembling module 300 to cure a plurality of adhesives connecting adjacent solar cell pieces of the photovoltaic arrangement 20 after the conductive tab element 30 and the first solar cell piece have been provided in an overlapping configuration by the assembling module 300.

In light of the above, embodiments described herein allow for a single curing operation in which both the adhesives connecting the adjacent solar cell pieces of the photovoltaic arrangement and the adhesive connecting the conductive tab element to the first solar cell piece are cured. Due to the fact that the inclusion of the conductive tab element in the photovoltaic arrangement is integrated into the assembling process and not performed as a separate operation after the solar cell pieces of the arrangement have been overlapped with each other, it is not necessary to cure the adhesive connecting the conductive tab element to the first solar cell piece in an additional curing operation after curing the adhesives connecting the adjacent solar cell pieces.

Curing an adhesive can be understood as drying or hardening the adhesive by heating the adhesive. Before the curing, the adhesive may be in a substantially liquid state, e.g. in the form of a paste. Curing the adhesive provides the adhesive in a substantially dried or hardened state. By curing the adhesives of the photovoltaic arrangement, adjacent solar cell pieces of the photovoltaic arrangement can be firmly connected with each other and the conductive tab element can be firmly attached to the first solar cell piece.

The transportation unit 650 as described herein may be arranged to transport the photovoltaic arrangement to the heating module 830.

A heating module 830 as described herein may include one or more heating elements, particularly a plurality of heating elements. A heating element may, for example, be a heating lamp, a heating resistor or a hot nest. The apparatus 100 may include a transportation unit, e.g. transportation unit 650 as described herein or a different transport unit, for transporting the photovoltaic arrangement 20 through the heating module 830. The one or more heating elements can be arranged above or below a surface of the transportation unit, e.g. for heating the photovoltaic arrangement 20 as the photovoltaic arrangement 20 supported by the surface is transported through the heating module 830.

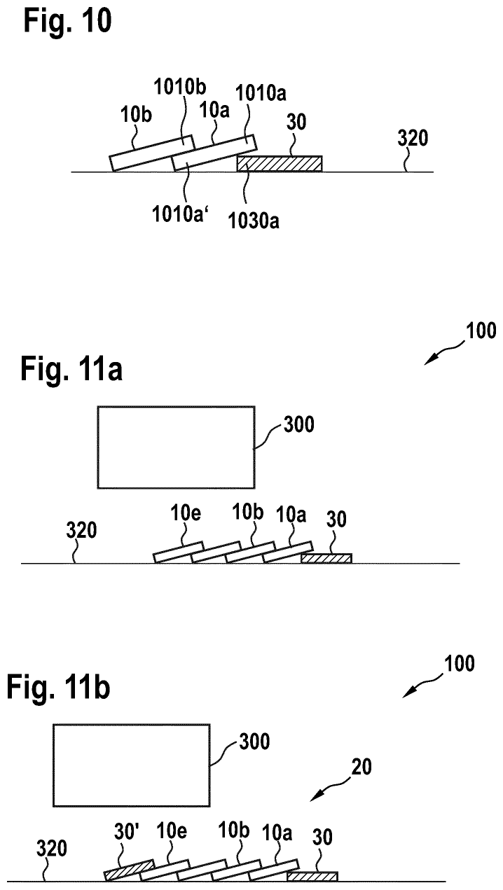

FIG. 10 shows an example of a conductive tab element 30 and a solar cell piece 10a that have been provided in an overlapping configuration by an assembling module 300 as described herein.

An assembling module 300 as described herein may be configured to provide the first solar cell piece (e.g. solar cell piece 10a shown in FIG. 10) and the conductive tab element 30 in an overlapping configuration in a manner such that a first edge region 1010a of the first solar cell piece is above an edge region 1030a of the conductive tab element 30.

A controller as described herein may be configured to control a movement of the one or more positioning devices to provide the first solar cell and the conductive tab element 30 in an overlapping configuration in a manner such that a first edge region 1010a of the first solar cell piece is above an edge region 1030a of the conductive tab element 30.

The assembling module 300 may be configured (e.g. under the control of the controller) to provide the second solar cell piece (e.g. solar cell piece 10b shown in FIG. 10) and the first solar cell piece in an overlapping configuration in a manner such that an edge region 1010b of the second solar cell piece is above a second edge region 1010a′ of the first solar cell piece. The first edge region 1010a and the second edge region 1010a′ may be at opposite ends of the first solar cell piece. Alternatively, the assembling module 300 may be configured to provide the second solar cell piece (e.g. solar cell piece 10b shown in FIG. 4c) and the third solar cell piece as described herein (e.g. solar cell piece 10c shown in FIG. 4c) in an overlapping configuration in a manner such that an edge region of the second solar cell piece is above an edge region of the third solar cell piece.

FIGS. 11a-b show an apparatus 100 according to embodiments described herein. FIG. 11a shows the apparatus 100 after the conductive tab element 30 and a plurality of solar cell pieces, including solar cell pieces 10a, 10b and 10e, have been positioned in respective overlapping configurations on the first support surface 320 by the assembling module 300. FIG. 11b shows the apparatus 100 after the assembling module 300 has positioned a second conductive tab element 30′ of the photovoltaic arrangement 20 in an overlapping configuration with respect to the solar cell piece 10e.

A conductive tab element 30 as described herein can be a first conductive tab element at a first end of the photovoltaic arrangement 20. The assembling module 300 may be configured to position a second conductive tab element 30′ to overlap with a solar cell piece (e.g. solar cell piece 10e shown in FIGS. 11a-b) at a second end of the photovoltaic arrangement 20. The first end may be opposite the second end. The solar cell piece at the second end of the photovoltaic arrangement 20 may be a last solar cell piece of the photovoltaic arrangement 20.

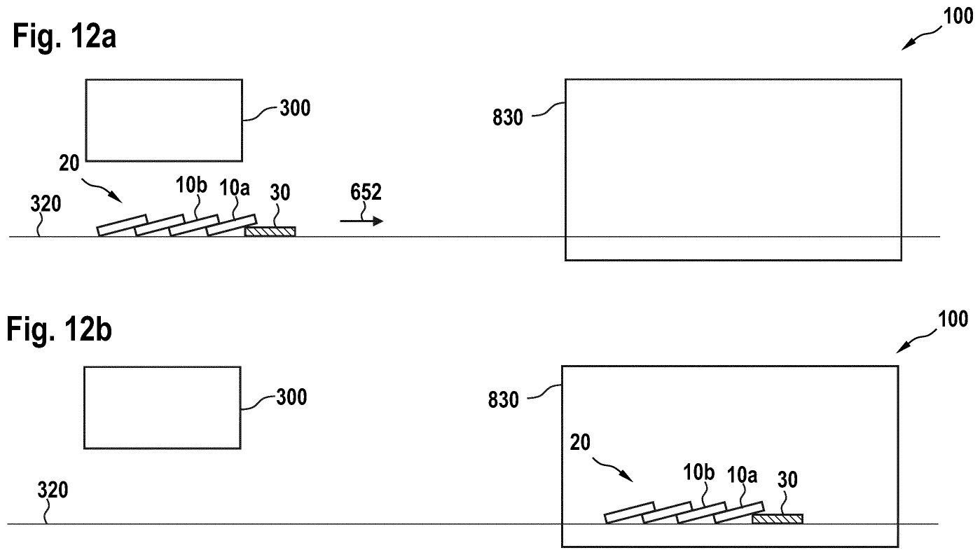

FIGS. 12a-b show an apparatus 100 according to embodiments described herein. The apparatus 100 includes an assembling module 300 as described herein and a heating module 830 as described herein. The heating module 830 is downstream of the assembling module 300. A photovoltaic arrangement 20 including a conductive tab element 30 and a plurality of overlapping solar cell pieces is assembled by the assembling module 300. Thereafter, the assembled photovoltaic arrangement 20 is cured by the heating module 830.

According to a further embodiment, an apparatus 100 for manufacturing a photovoltaic arrangement 20 is provided. The apparatus 100 includes an assembling module 300 for assembling a photovoltaic arrangement 20 comprising a conductive tab element 30 and a plurality of overlapping solar cell pieces. The apparatus 100 includes a heating module 830 downstream of the assembling module 300 to cure the photovoltaic arrangement 20 including the conductive tab element and the plurality of overlapping solar cell pieces.

The heating module 830 may be downstream of the assembling module 300 relative to a processing flow of the apparatus 100, as e.g. indicated by transport direction 652 in FIG. 12a.

The apparatus 100 can include a transportation unit (e.g. transportation unit 650 as described herein) for transporting the photovoltaic arrangement 20 including the conductive tab element 30 and the plurality of overlapping solar cell pieces from the assembling module 300 to the heating module 830. In the photovoltaic arrangement 20 which is transported to the heating module 830 by the transportation unit, the first solar cell piece and the conductive tab element 30 may be in an overlapping configuration in a manner such that a leading edge of the first solar cell piece follows a leading edge of the conductive tab element 30, e.g. relative to a transport direction 652 as described herein.

As described above, the assembling module 300 may be configured to provide the first solar cell piece and the conductive tab element 30 in an overlapping configuration in a manner such that a first edge region of the first solar cell piece is above an edge region of the conductive tab element 30. Thereafter, the photovoltaic arrangement 20 may be cured by the heating module 830.

According to a further embodiment, a method of manufacturing a photovoltaic arrangement 20 comprising a conductive tab element 30 and a plurality of overlapping solar cell pieces is provided. The method includes assembling a partial photovoltaic arrangement comprising a first solar cell piece (e.g. solar cell piece 10a as described herein) and the conductive tab element 30, the assembling comprising providing the first solar cell piece and the conductive tab element 30 in an overlapping configuration. The method includes providing a second solar cell piece (e.g. solar cell piece 10b as described herein) and a solar cell piece of the partial photovoltaic arrangement in an overlapping configuration. The second solar cell piece and the solar cell piece of the partial photovoltaic arrangement are provided in an overlapping configuration after providing the first solar cell piece and the conductive tab element 30 in an overlapping configuration. The solar cell piece of the partial photovoltaic arrangement may be the first solar cell piece or a third solar cell piece (e.g. the solar cell piece 10c shown in FIG. 4c).

The method according to embodiments described herein may include placing the conductive tab element 30 on a first support surface 320. The method may include placing the first solar cell piece on the first support surface 320. The method may include placing the second solar cell piece on the first support surface 320.

The method according to embodiments described herein may include placing the conductive tab element 30 on a first support surface 320 (e.g. using a second positioning device as described herein) and, thereafter, placing the first solar cell piece on the first support surface 320 (using a first positioning device as described herein).

The method according to embodiments described herein may include transporting the conductive tab element 30 and the first solar cell piece in a transport direction as described herein, e.g. transport direction 652.

The method according to embodiments described herein may include storing the conductive tab element, e.g. in a storing unit 750 as described herein. The method may include transferring the conductive tab element 30 from the storing unit 750 to the first support surface 320, e.g. by a transfer system as described herein.

The method according to embodiments described herein may include arranging the conductive tab element 30 and the first solar cell piece in a manner such that a leading edge 610a of the first solar cell piece follows a leading edge 630 of the conductive tab element 30.

The first solar cell piece and the conductive tab element 30 may be provided in an overlapping configuration in a manner such that a first edge region 1010a of the first solar cell piece is above an edge region 1030a of the conductive tab element 30.

The method according to embodiments described herein may include curing the photovoltaic arrangement 20 after providing the second solar cell piece (e.g. the solar cell piece 10b) and the solar cell piece of the partial photovoltaic arrangement (e.g. the solar cell piece 10a or the solar cell piece 10c) in an overlapping configuration. Curing the photovoltaic arrangement may include jointly curing a first adhesive connecting the conductive tab element 30 with the first solar cell piece and a second adhesive connecting the second solar cell piece with the solar cell piece of the partial photovoltaic arrangement. The curing may be carried out by a heating module 830 as described herein.

While the foregoing is directed to embodiments of the disclosure, other and further embodiments of the disclosure may be devised without departing from the basic scope thereof, and the scope thereof is determined by the claims that follow.

1. An apparatus for manufacturing a photovoltaic arrangement comprising a conductive tab element and a plurality of overlapping solar cell pieces, the apparatus comprising:
an assembling module configured for:
assembling a partial photovoltaic arrangement comprising a first solar cell piece and the conductive tab element, the assembling comprising providing the first solar cell piece and the conductive tab element in an overlapping configuration; and, after providing the first solar cell piece and the conductive tab element in the overlapping configuration,
providing a second solar cell piece and a solar cell piece of the partial photovoltaic arrangement in an overlapping configuration, wherein the solar cell piece of the partial photovoltaic arrangement is the first solar cell piece or a third solar cell piece;
a first adhesive application device upstream of the assembling module, the first adhesive application device being a printing device, wherein:
the first adhesive application device is configured for applying an adhesive to a solar cell piece; or
the apparatus further comprises a solar cell separation device, the first adhesive application device being arranged upstream of the solar cell separation device for applying an adhesive to a solar cell before the solar cell is separated into solar cell pieces by the solar cell separation device; and
a heating module downstream of the assembling module to cure the photovoltaic arrangement including the conductive tab element and the plurality of overlapping solar cell pieces.

2. The apparatus according to claim 1, further comprising a first support surface, wherein the assembling module comprises one or more positioning devices configured to place the conductive tab element and the first solar cell piece on the first support surface.

3. The apparatus according to claim 2, wherein the one or more positioning devices are configured to place the conductive tab element on the first support surface and thereafter place the first solar cell piece on the first support surface.

4. The apparatus according to claim 2, further comprising:
a transportation unit defining a transport direction, the first support surface being a surface of the transportation unit,
the one or more positioning devices being configured to place the conductive tab element and the first solar cell piece on the first support surface in a manner such that a leading edge of the first solar cell piece follows a leading edge of the conductive tab element.

5. The apparatus according to claim 2, further comprising:
a storing unit for storing the conductive tab element,
a transfer system for transferring the conductive tab element from the storing unit to the first support surface.

6. The apparatus according to claim 1, wherein the assembling module is configured to provide the first solar cell piece and the conductive tab element in an overlapping configuration in a manner such that an edge region of the first solar cell piece is above an edge region of the conductive tab element.

7. (canceled)

8. (canceled)

9. The apparatus according to claim 1, wherein the conductive tab element is a first conductive tab element at a first end of the photovoltaic arrangement,
wherein the assembling module is configured to position a second conductive tab element to overlap with a solar cell piece at a second end of the photovoltaic arrangement.

10. An apparatus for manufacturing a photovoltaic arrangement, comprising:
an assembling module for assembling a photovoltaic arrangement comprising a conductive tab element and a plurality of overlapping solar cell pieces; and
a heating module downstream of the assembling module to cure the photovoltaic arrangement including the conductive tab element and the plurality of overlapping solar cell pieces.

11. A method of manufacturing a photovoltaic arrangement comprising a conductive tab element and a plurality of overlapping solar cell pieces, the method comprising:
assembling, by an assembling module, a partial photovoltaic arrangement comprising a first solar cell piece and the conductive tab element, the assembling comprising providing the first solar cell piece and the conductive tab element in an overlapping configuration; and, after providing the first solar cell piece and the conductive tab element in the overlapping configuration,
providing, by the assembling module, a second solar cell piece and a solar cell piece of the partial photovoltaic arrangement in an overlapping configuration, wherein the solar cell piece of the partial photovoltaic arrangement is the first solar cell piece or a third solar cell piece;
the method further comprising:
performing one of the following by a first adhesive application device upstream of the assembling module, the first adhesive application device being a printing device:
applying an adhesive to a solar cell piece; or
applying an adhesive to a solar cell before the solar cell is separated into solar cell pieces; and
jointly curing a first adhesive connecting the first solar cell piece with the conductive tab element and a second adhesive connecting the second solar cell piece with the solar cell piece of the partial photovoltaic arrangement.

12. The method according to claim 11, further comprising:
placing the conductive tab element on a first support surface and, thereafter, placing the first solar cell piece on the first support surface.

13. The method according to claim 11 or claim 12, further comprising:
transporting the conductive tab element and the first solar cell piece in a transport direction; and
arranging the conductive tab element and the first solar cell piece in a manner such that a leading edge of the first solar cell piece follows a leading edge of the conductive tab element.

14. The method according to claim 11 to 13, wherein the first solar cell piece and the conductive tab element are provided in an overlapping configuration in a manner such that an edge region of the first solar cell piece is above an edge region of the conductive tab element.

15. (canceled)

16. The apparatus according to claim 2, wherein the one or more positioning devices include a gripper configured to hold and/or move a plurality of solar cell pieces jointly.

17. The apparatus according to claim 10, further comprising a first adhesive application device upstream of the assembling module, the first adhesive application device being a printing device, wherein:
the first adhesive application device is configured for applying an adhesive to a solar cell piece; or
the apparatus further comprises a solar cell separation device, the first adhesive application device being arranged upstream of the solar cell separation device for applying an adhesive to a solar cell before the solar cell is separated into solar cell pieces by the solar cell separation device.

18. The apparatus according to claim 10, wherein the photovoltaic arrangement includes a first solar cell piece, the apparatus further comprising a first support surface, wherein the assembling module comprises one or more positioning devices configured to place the conductive tab element and the first solar cell piece on the first support surface.

19. The apparatus according to claim 18, wherein the one or more positioning devices include a gripper configured to hold and/or move two or more solar cell pieces jointly.

20. The apparatus according to claim 18, further comprising:
a transportation unit defining a transport direction, the first support surface being a surface of the transportation unit,
the one or more positioning devices being configured to place the conductive tab element and the first solar cell piece on the first support surface in a manner such that a leading edge of the first solar cell piece follows a leading edge of the conductive tab element.

21. The apparatus according to claim 10, further comprising a transportation unit for transporting the photovoltaic arrangement including the conductive tab element and the plurality of overlapping solar cell pieces from the assembling module to the heating module.

22. The apparatus according to claim 10, wherein the conductive tab element is a first conductive tab element at a first end of the photovoltaic arrangement,
wherein the assembling module is configured to position a second conductive tab element to overlap with a solar cell piece at a second end of the photovoltaic arrangement.

23. The method according to claim 11, wherein the assembling module comprises one or more positioning devices including a gripper configured to hold and/or move a plurality of solar cell pieces jointly, the method further comprising:
placing the conductive tab element and the first solar cell piece on a first support surface using the one or more positioning devices.
